(19) United States
(12) Patent Application Publication
(10) Pub. No.: US 2015/0332897 A1
(43) Pub. Date: Nov. 19, 2015

(54) IGNITION PROCESS AND DEVICE FOR PAIRS OF DBD ELECTRODES

(71) Applicant: ASAHI GLASS COMPANY LIMITED, Chiyoda ku, Tokyo (JP)

(72) Inventors: M. Eric TIXHON, Crisnee (BE); M. Eric MICHEL, Glain (BE); M. Joseph LECLERCQ, Sart en Fagne (BE)

(73) Assignee: ASAHI GLASS COMPANY LIMITED, Chiyoda-ku, Tokyo (JP)

(21) Appl. No.: 14/654,307

(22) PCT Filed: Dec. 18, 2013
(86) PCT No.: PCT/JP2013/007432

§ 371 Date: Jun. 19, 2015

(30) Foreign Application Priority Data
Dec. 21, 2012 (EP) 12199066.7

(51) Int. Cl. H01J 37/32; C23C 16/455; C23C 16/50

(52) U.S. Cl. CPC H01J 37/32532; C23C 16/50; C23C 16/455

(57) ABSTRACT

A process for surface treatment by dielectric barrier discharge (DBD) comprising the following operations:—feeding or passing a substrate into a reaction chamber (2), in which at least two electrodes (10, 12) and at least one counter-electrode (13, 14, 15) are positioned, wherein at least one dielectric barrier (16) is placed between these at least two electrodes (10, 12) and this at least one counter-electrode (13, 14, 15);—switching an inductance (L1, L2) in series with each of said electrodes (10, 12), wherein said inductances (L1, L2) are wound onto a common magnetic core in such a manner that the resulting magnetic flux of the two inductances is zero when identical currents circulate in the two electrodes (10, 12);—generating a high-frequency electric voltage of such a value that it causes the generation of a plasma between the at least two electrodes (10, 12) and the at least one counter-electrode (13, 14, 15);—feeding into the reaction chamber a mixture, the composition of which is such that on contact with the plasma, it breaks down and generates substances able to react with the surface of the substrate (4);

### TECHNICAL FIELD

The invention relates to dielectric barrier discharge processes for the surface treatment of substrates. In particular, the invention concerns the ignition when the surface treatment is conducted by at least two electrodes and at least one counter-electrode positioned on either side of the substrate.

The invention also relates to an installation equipped with the ignition in question.

### BACKGROUND ART

A process for depositing layers onto a substrate by dielectric barrier discharge is known from document EP 2145978. The described process includes in particular the insertion or passage of a substrate in a reaction chamber, in which an electrode and a counter-electrode are positioned. A dielectric barrier is placed between this electrode and this counter-electrode. A high-frequency electric voltage that causes the generation of a plasma is generated between the electrode and the counter-electrode. A gaseous composition is fed into the reaction chamber that upon contact with the plasma reacts with the surface of the substrate. An adjustable inductance (L) arranged in parallel with the inductance of the installation generating the electric voltage is put into operation in order to reduce the phase shift between the voltage and the generated current and increase the passage time of the current in the plasma.

In the interest of increasing the efficiency of the process, it has already been envisaged to use two electrodes placed side by side, the current passing from these electrodes to corresponding counter-electrodes and the introduction of the reactive mixture thus occurring at the space separating the two electrodes. In such a process the virtually unavoidable consequence of small imperfections in the geometry of the electrodes and the counter-electrode or temperature differences is that the plasma preferably ignites under a single electrode. The resulting voltage at the terminals of the electrodes after ignition thus stabilises at the value of the discharge according to Paschen's law. This voltage no longer allows the ignition of the second electrode, since it is lower than the value of the sparkover voltage of the discharge. The result is that the injected reactive product is lost to 50% and the growth rate of the layer is slowed down in the same manner. Since it is impossible to form perfect electrodes and to compensate any temperature differences, to be able to ignite both electrodes a solution is to split the transformer supplying the system in order to provide a transformer for each electrode pair. This solution is not, of course, advantageous from the economic viewpoint since splitting of the transformer is costly.

Another solution described in WO 99/04411 is to use ballast inductances connected in series with each electrode. However, during operation after ignition of the two electrodes this assembly entails boosting the supply of the reactor.

### SUMMARY OF INVENTION

An aim of the invention is to solve the ignition problem that classically arises in a DBD process using at least two electrodes arranged side by side to perform the surface treatment.

Another aim of the invention is to improve the efficiency and efficacy of such a process.

The invention relates to a process for surface treatment by dielectric barrier discharge comprising the following operations:
feeding or passing a substrate into a reaction chamber, in which at least two electrodes and at least one counter-electrode are positioned, wherein at least one dielectric barrier is placed between these at least two electrodes and this at least one counter-electrode;
generating a high-frequency electric voltage of such a value that it causes the generation of a plasma between these at least two electrodes and the at least one counter-electrode;
feeding into the reaction chamber a mixture, the composition of which is such that on contact with the plasma, it breaks down and generates substances able to react with the surface of the substrate;
connecting an inductance in series with each of said electrodes, wherein the value of said inductances is such that in the case where the plasma ignites under a single electrode, the current circulating in the inductance in series with this electrode causes a magnetic flux in the other inductance, and such that the resulting voltage at the terminals of this second inductance causes an increase in the voltage at the terminals of the electrode that remains unignited forcing the ignition thereof, wherein said inductances are wound on a common magnetic core so that the resulting magnetic flux of the two inductances is zero when identical currents circulate in the two electrodes.

It will be noted that the process of the invention is defined in terms of “operations” rather than “steps”, i.e. that the succession of operations does not necessarily occur in the order in which they are outlined above.

“Surface treatment” is understood here to mean any operation for preparing, cleaning, coating or depositing one or more layers on the surface of a substrate.

There is thus defined an ignition device that is suitable for being connected in series on the at least two electrodes and comprises two inductances wound onto a common magnetic core having windings such that the magnetic fluxes produced by the two inductances cancel one another out when identical currents circulate in the two electrodes.

In the ignition device the value of the inductances (L1, L2) arranged in series with each of the electrodes is calculated such that when the plasma ignites under a single electrode, the current circulating in the inductance in series with this electrode causes a magnetic flux in the other inductance, and that the voltage resulting at the terminals of this second inductance causes an increase in the voltage at the terminals of the capacitor formed by the electrode that remains unignited and the corresponding counter-electrode.

When the two electrodes are ignited, the currents are balanced and the magnetic fluxes caused in the inductances assembled in series with the electrodes cancel one another out because the currents circulating across the two electrodes are essentially identical, which results in the impedances of these inductances being cancelled out. This characteristic is very important because when the assembly is started up, it is not necessary to boost the supply of the electrodes or to initiate any correction on the possible compensator coil.

The principle also applies in the same manner, mutatis mutandis, in the case where two pairs of electrodes are used.

The choice of value of the inductances is dependent on several functions, in particular the current between electrode and counter-electrode(s), wherein this current is itself dependent on the frequency and the geometry of said electrodes. Advantageously, if the voltage variation (dV) resulting from a preferred ignition at one of the electrodes causes a differential current (dI) with that of the electrode that remains unignited, the value of each inductance (1) will be such that dV=ω.l.dI, from which 1=dV/ω.dI, with ω=2πf and f is the frequency of the HF supply source.

According to an advantageous embodiment the winding of the inductances in series with each of said electrodes wound on a common magnetic core is reversed.

According to an advantageous embodiment the reactive mixture is fed via a passage into the reaction chamber opening into the space separating the two electrodes.

According to an advantageous embodiment the plasma is generated on either side of the substrate between the two electrodes and the counter-electrode and the reactive mixture fed into the reaction chamber is fed on either side of the substrate. Such a process allows a surface treatment to be achieved on each side of the substrate.

According to an advantageous embodiment the plasma is generated on either side of the substrate between the two electrodes and the counter-electrode and reactive mixtures of different compositions are fed into the reaction chamber on either side of the substrate. Such a process allows a different surface treatment to be achieved on each side of the substrate.

According to an advantageous embodiment the mixtures fed into the reaction chamber on either side of the substrate are confined in two separate zones by mechanical barriers. The substrate itself can be part of these mechanical barriers.

According to an advantageous embodiment two counter-electrodes facing the two electrodes are placed side by side in order to feed the reactive mixture via a passage into the reaction chamber opening onto the space separating the two counter-electrodes.

According to a preferred embodiment the process additionally comprises the following operations:
putting into operation an adjustable inductance arranged in parallel with the inductance of the installation itself that generates the electric voltage in order to reduce the phase shift between the voltage and the current supplied by the HF source;
adapting the voltage and/or the frequency supplied by the generator circuit and/or the adjustable value of the inductance at the start of or during the course of the process in order to obtain optimum reaction characteristics.

An advantage of this variant is that the introduction of an inductance into the circuit improves the power factor of the installation and hence increases its efficiency considerably. Another advantage of this variant is that it also allows the process to generate sufficient active energy to obtain elevated deposition rates while improving the properties of the deposited layers.

According to a preferred embodiment the voltage and/or the frequency supplied by the generator circuit and/or the value of the inductance are modulated in order to stimulate the production of harmonics that on each half-period extend the time, during which the voltage remains higher than the value of maintaining the arc, which results in extension of the generation time of the plasma. Harmonics in the order of 3 and 5 are preferably stimulated. An advantage of this embodiment is that with equal amount of power consumed, the efficacy of the process is substantially improved.

According to an advantageous embodiment the process additionally comprises the following operation: causing the position of the electrodes to vary in order to obtain optimum reaction characteristics. This can enable the characteristics of the electrical circuit to be varied and thus allow the configuration of the current to be influenced.

According to a particular embodiment the process additionally comprises the following operation: bringing the atmosphere prevailing in the chamber to a determined pressure that can be lower than atmospheric pressure.

Advantageously, the substrate is insulating and itself forms one of the dielectric barriers placed between the at least two electrodes.

Moreover, if the substrate is conductive, it can itself form one of the electrodes.

The mixture is fed into the reaction chamber preferably in the form of a liquid by spraying, of a reactive gas or powder.

The invention also relates to an installation for surface treatment by dielectric barrier discharge on a substrate comprising a chamber, transport means and support means for inserting a substrate into the chamber. A high-voltage and high-frequency power supply is connected to the two pairs of electrodes placed on either side of the substrate and at least one dielectric barrier is arranged between the at least two electrodes. Means for adjusting and controlling the power supply are provided, as are means for feeding reactive substances into the chamber and means for extracting background gases. In this installation an inductance is arranged in series with each pair of electrodes, wherein the value of these inductances is calculated to cause ignition of the second pair of electrodes, as explained above.

According to a preferred embodiment an adjustable inductance is arranged in parallel with the supply circuit. The characteristics of this adjustable inductance are such that it allows the phase shift between the voltage generated between the electrodes and the total current supplied by the high-voltage source to be modulated. In this installation the means for adjusting the power supply and the means for controlling the inductance are advantageously coupled in order to allow the generation of harmonics that at each half-period extend the time the value of the voltage between the electrodes is held at a value higher than that of maintaining the electric discharge.

According to an advantageous embodiment the chamber is open at its two ends, which allows the surface treatment process to be integrated into an installation for continuous production. For example, the chamber can advantageously be integrated into an annealing lehr of a float glass production line, wherein the support means for the substrate comprise at least one roller.

According to an advantageous embodiment the chamber is open at its two ends, which allows the surface treatment process to be integrated into an installation for continuous production. In this context, the chamber can advantageously be integrated into a float glass production line, wherein the support means for the substrate comprise a tin bath.

According to another preferred embodiment the chamber is closed, which allows the process of the invention to be integrated into a discontinuous surface treatment operation. The chamber can be positioned, for example, on “magnetron sputtering” treatment lines.

Advantageously the plasma can be generated in two separate zones arranged on either side of the substrate in such a manner that a layer is deposited onto each of the faces of this substrate simultaneously.

### BRIEF DESCRIPTION OF DRAWINGS

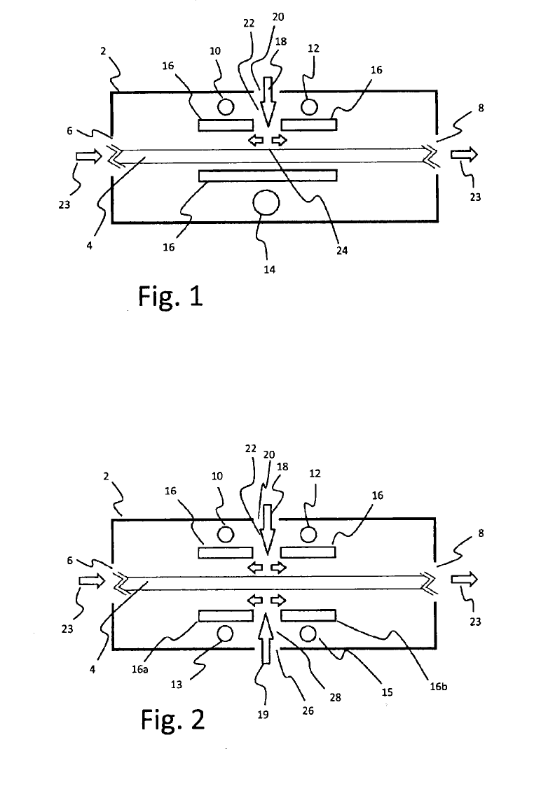

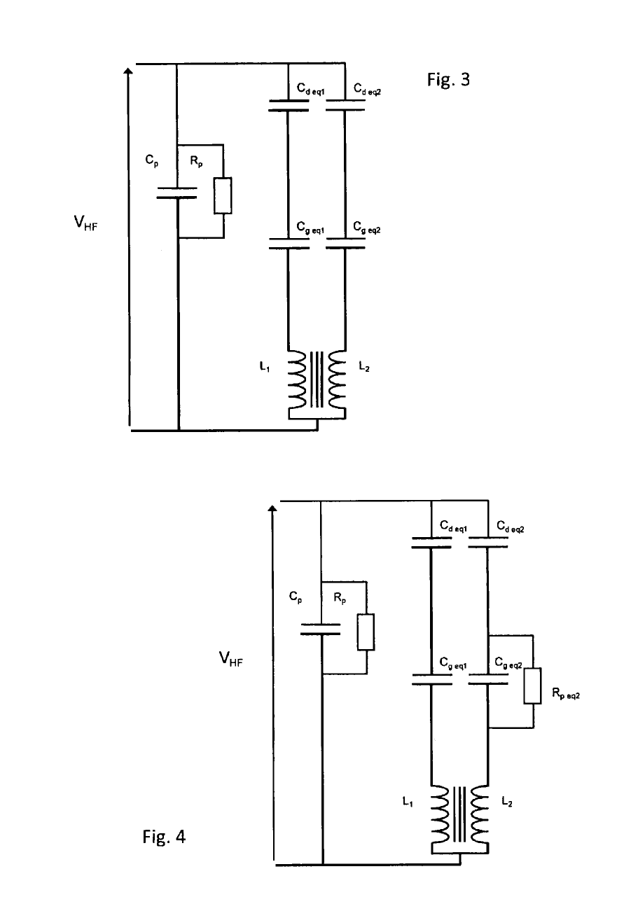

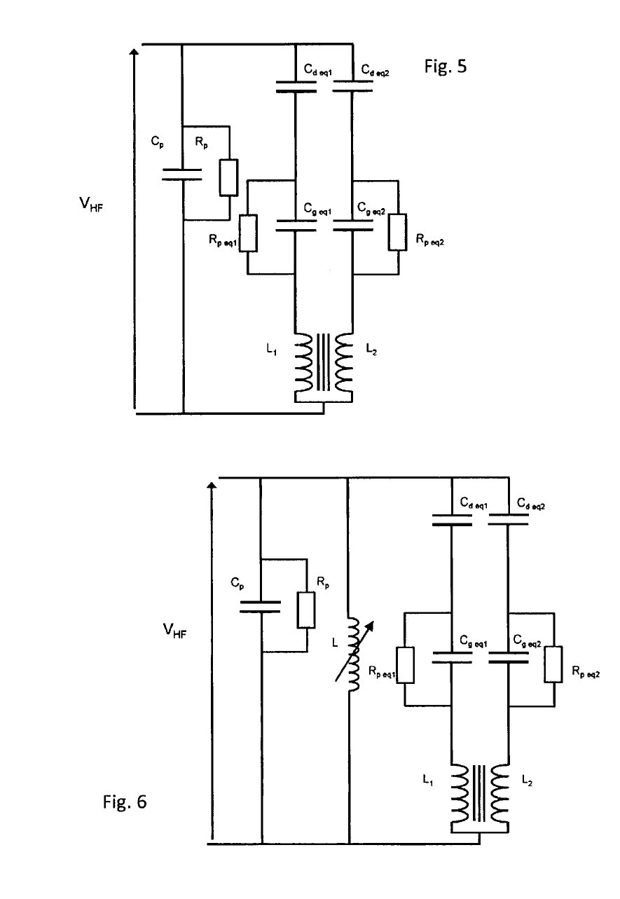

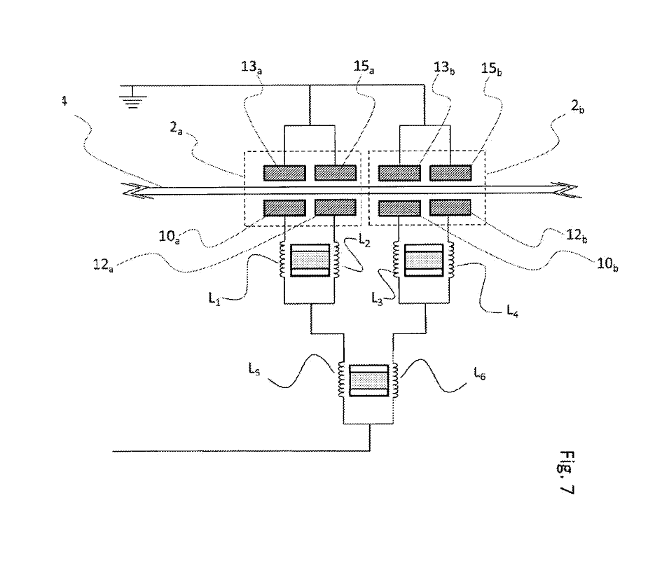

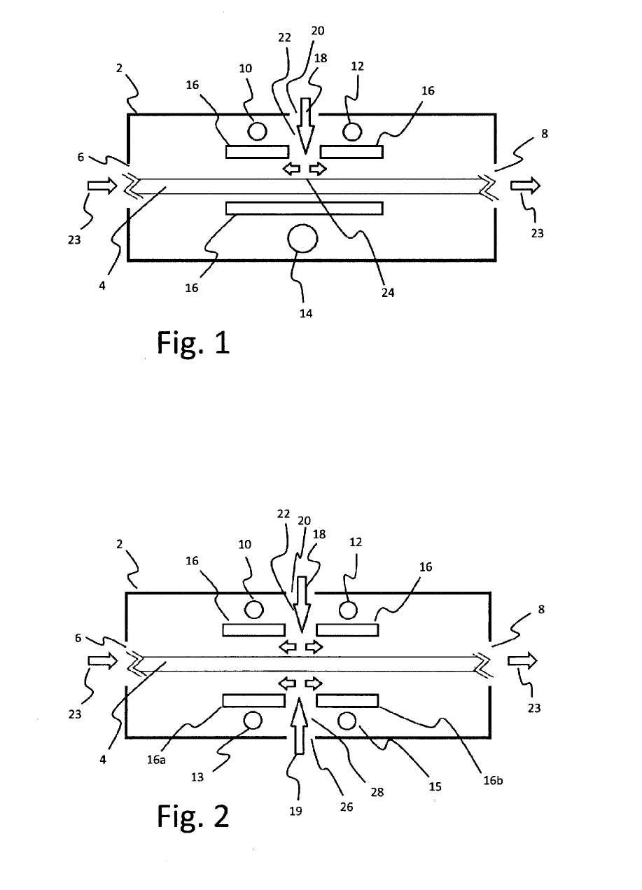

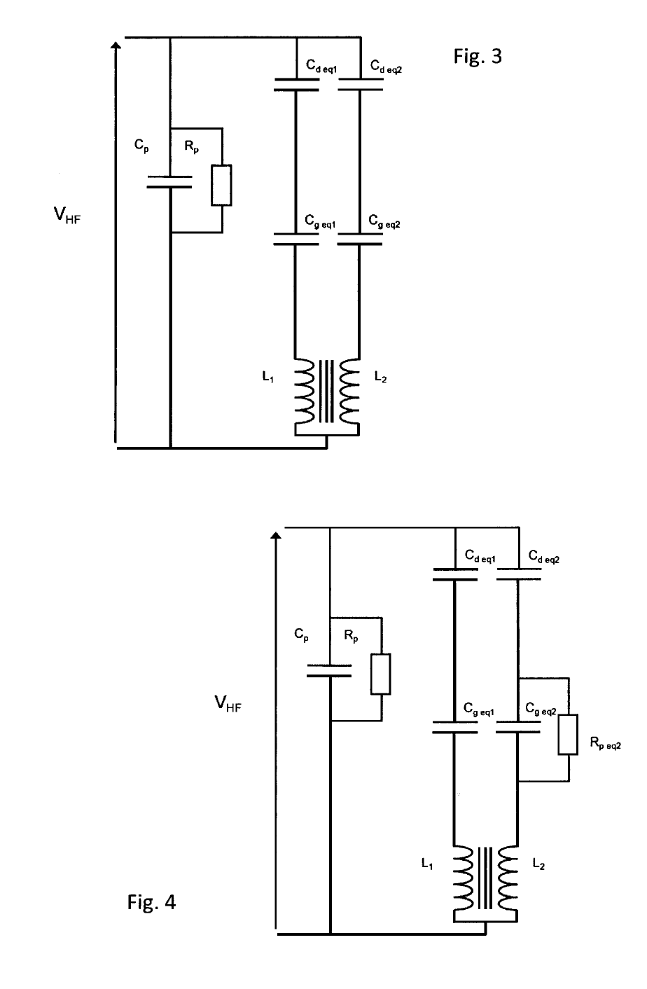

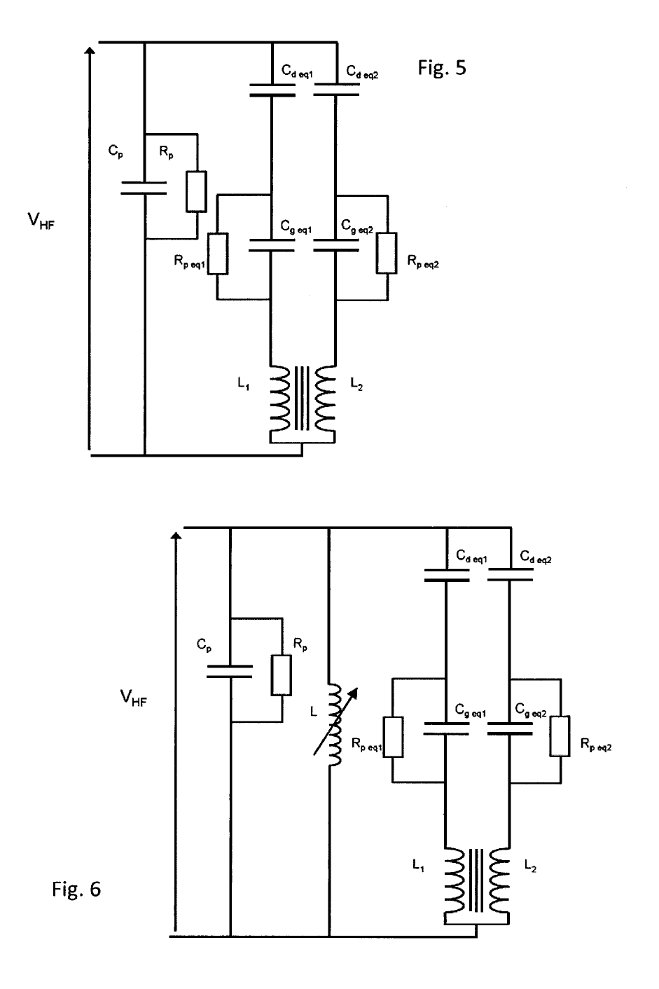

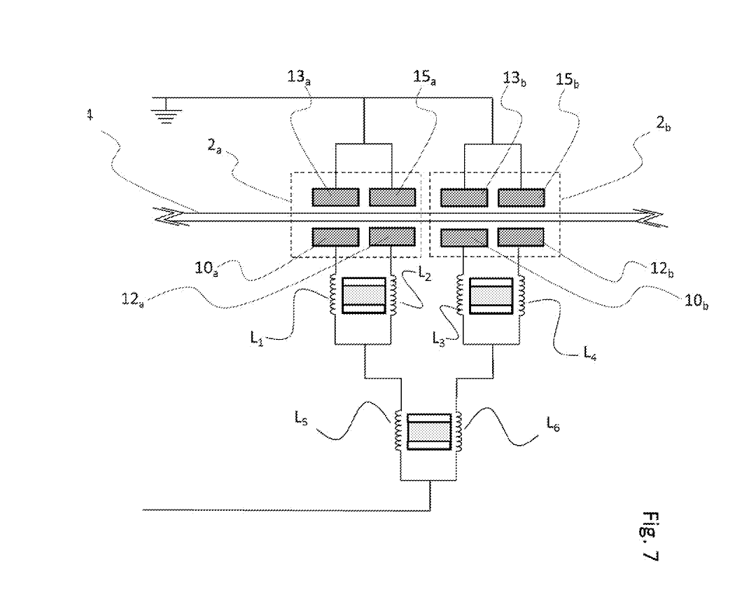

These aspects as well as other aspects of the invention will be clarified in the detailed description of particular embodiments of the invention with reference to the drawings of the figures, wherein:

[FIG. 1]FIG. 1 is a schematic front view of an installation for depositing layers on a substrate;

[FIG. 2]FIG. 2 is a schematic front view of an installation for depositing layers on both faces of a substrate;

[FIG. 3]FIG. 3 is an equivalent circuit diagram of the installation before formation of the plasma in the case of a deposition on one of the two faces of the substrate or on both faces of the substrate;

[FIG. 4]FIG. 4 is an equivalent circuit diagram of the installation after ignition of the plasma under one of the two electrodes in the case of a deposition on one of the two faces of the substrate or on both faces of the substrate;

[FIG. 5]FIG. 5 is an equivalent circuit diagram of the installation after ignition of the plasma under both electrodes in the case of a deposition on one of the two faces of the substrate or on both faces of the substrate;

[FIG. 6]FIG. 6 is an equivalent circuit diagram of the installation after ignition of the plasma under both electrodes in the case of a deposition on one of the two faces of the substrate or on both faces of the substrate according to another embodiment of the invention.

[FIG. 7]FIG. 7 is a schematic front view of an installation for depositing layers on a substrate;

The figures are not drawn to scale. In general, similar elements are represented by similar references in the figures.

### DESCRIPTION OF EMBODIMENTS

FIG. 1 shows an open chamber 2 designed for a continuous process for depositing layers on a glass substrate. The glass substrate 4 is inserted through an inlet 6, then passes inside this deposition chamber 2 before exiting again through an outlet 8. A high-frequency high voltage is applied between two electrodes 10, 12 and a counter-electrode 14. A dielectric barrier 16 is placed between the two electrodes 10, 12 and the counter-electrode 14. The difference in potential between the two electrodes 10, 12 and the counter-electrode 14 causes the generation of a plasma. A reactive mixture 18 is fed into the deposition chamber 2. Using multiple electrodes, below which the substrate 4 passes successively, results in the total surface area of the electrodes being increased. Compared to a process that only uses one electrode and one counter-electrode, this allows the thickness of the deposit to be increased or, alternatively with an identical thickness of deposit, allows the passage rate of the substrate inside the chamber to be increased. In practice, in the case of using two electrodes 10, 12 facing a counter-electrode 16, the reactive mixture 18 is ideally fed through a passage 20 into the deposition chamber 2 opening into the space 22 separating the two electrodes 10, 12. This allows an ideal and rapid distribution of reactive ions 18 in the deposition zone 24. The arrows 23 indicate the direction of passage of the glass substrate 4.

FIG. 2 shows that it is also possible to conduct a deposition simultaneously on both faces of the glass substrate 4. In such a process the counter-electrode 14 of the previous assembly is replaced by a double counter-electrode formed from two counter-electrodes 13, 15 and the dielectric barrier 16 is replaced by a double dielectric barrier formed by two dielectric barriers 16a and 16b. The introduction of reactive gases 18, 19 occurs in this case through passages 20, 26 in the deposition reaction chamber 2 formed on either side of the substrate 4 opening onto the spaces 22, 28 that respectively separate the two electrodes and the two counter-electrodes.

The voltage applied between the electrodes and the counter-electrode or counter-electrodes is preferably in the range of between 1000 and 200 000 V peak to peak, more preferred between 5000 and 100 000 V peak to peak, and still more preferred between 10 000 and 40 000 V peak to peak. The frequency is preferably in the range of between 10 KHz and 1000 KHz, more preferred between 20 KHz and 400 KHz and still more preferred between 50 KHz and 200 KHz.

The electrodes and counter-electrodes of FIGS. 1 and 2 have been drawn as cylindrical electrodes, but may alternatively be flat.

As explained above, the use of two electrodes 10, 12 in the processes described in

FIG. 1 and FIG. 2 causes an ignition problem resulting from the fact that if the two electrodes are not ignited simultaneously, after ignition of the first electrode the voltage applied between the electrode that remains unignited and the counter-electrode or counter-electrodes 13, 14, 15 is no longer sufficient to ignite this second electrode. To resolve this problem a device comprising two identical coils wound onto a common magnetic core has been conceived. Each of the coils is connected in series with one of the electrodes 10, 12 and the winding of the two coils around the common magnetic core is performed to obtain two fluxes that cancel one another out as soon as both electrodes are ignited. This characteristic is highly advantageous because as soon as the assembly has started up, it is not necessary to boost the supply of the electrodes or to initiate any correction on the possible compensator coil.

In the ignition device the value of the inductances (L1, L2) arranged in series with each of the electrodes is calculated such that when the plasma ignites under a single electrode, the current circulating in the inductance in series with this electrode causes a magnetic flux in the other inductance, and that the voltage resulting at the terminals of this second inductance causes an increase in the voltage at the terminals of the capacitor formed by the electrode that remains unignited and the corresponding counter-electrode.

A highly simplified equivalent circuit diagram of the installation before start-up equipped with the device for forcing the ignition of the plasma under the two electrodes is shown in FIG. 3. A high-frequency (HF) high voltage is applied between the electrodes and the counter-electrode or counter-electrodes. The installation for discharge in the chamber amounts essentially to an addition of capacitors in parallel and in series, i.e. Cp (parasitic capacitance in parallel with a parasitic resistance Rp), Cd eq1, Cd eq2 (capacitance of the dielectric or dielectrics) and Cg eq1, Cg eq2 (capacitance of the gas or gases). L1 and L2 correspond to the inductances of the device to force the ignition of the plasma under both electrodes.

FIG. 4 shows the same diagram when the plasma is generated under a single electrode. At this instant, Cg eq2 is shunted by a resistance Rg eq2, which represents the resistance of the plasma under the first electrode.

FIG. 5 shows the same diagram again, but this time when the plasma is also generated under the second electrode under the action of the ignition device formed by L1 and L2. At this instant, Cg eq1 is shunted by a resistance Rg eq1, which represents the resistance of the plasma under the second electrode.

In the absence of discharge (i.e. as long as the voltage applied between the electrodes and the counter-electrode or counter-electrodes is lower than the sparkover voltage), the values of Rg eq1 and Rg eq2 are extremely high, which explains why it is not necessary to take them into consideration in circuits modelling the system in the absence of discharge and the total current supplied by the source is practically solely capacitive. During the course of the discharge resistive currents Ig1 and Ig2 appear under each electrode and are the electrical sign of the deposit conducted on the substrate.

FIG. 6 shows the equivalent circuit diagram of the routine operation of a surface treatment installation according to the invention, in which an adjustable inductance (L) arranged in parallel with the inductance of the installation itself that generates the electric voltage is put into operation. The value for the adjustable inductance (L) is chosen in order to reduce the phase shift between the voltage and the current supplied by the HF source. The insertion of this inductance into the circuit improves the power factor of the installation and hence increases its efficiency considerably. It will be evident to a person skilled in the art that the present invention is not limited to the examples illustrated and described above. The invention includes each of the novel characteristics as well as combinations thereof. The presence of reference numbers cannot be considered as restrictive. The use of the term “comprises” cannot in any way exclude the presence of elements other than those mentioned. The use of the indefinite article “a” to introduce an element does not exclude the presence of a plurality of these elements. The present invention has been described in relation to specific embodiments, which are of purely illustrative value and must not be considered as restrictive.

FIG. 7 shows another installation for the surface treatment of a substrate according to the present invention comprising two chambers 2a, 2b designed for a continuous process for depositing layers on a glass substrate 4. Such an installation can offer the possibility of, for example, successively coating a substrate with two layers of different nature, or first treat the substrate, then deposit a coating on it, or coating the substrate with a thicker coating. In the embodiment of FIG. 7, an installation for the surface treatment of a substrate as described hereinabove is doubled: (i) a first sub-installation comprising chamber 2a and primary inductances L1, L2 switched in series with each of said electrodes 10a, 12a, and (ii) a second sub-installation comprising chamber 2b and primary inductances L3, L4 switched in series with each of said electrodes 10b, 12b. Counter-electrodes are denoted 13a, 15a and 13b, 15b. These two sub-installations are supplied with a single VHF or HF source and secondary inductances L5 and L6 allow equilibrate the currents in both chambers 2a and 2b (by “equilibrate the currents”, we mean having substantially identical currents at the entrance of both chambers, i.e. at the entrance of the primary inductances). L1, L2 and L3, L4 allow, as hereinabove described, equilibrate the currents and force the ignition of the plasma under each pair of electrodes in their respective chamber. This embodiment shows that a device comprising a double inductance system as described hereinabove for an installation with two pairs of electrodes may also apply to solve the ignition of two sub-installations each having two pairs of electrodes but supplied with a single HF source.

In the example of FIG. 7, it was chosen to:
use the glass substrate as dielectric barrier, therefore, no other dielectric barrier was included between the electrodes and counter-electrodes
draw the electrodes and counter-electrodes as “flat” electrodes.

If such an installation is used to coat the substrate, the coating will be formed on the lower face of glass substrate 4.

1. A process for surface treatment by dielectric barrier discharge (DBD) comprising the following:
feeding or passing a substrate into a reaction chamber, in which at least two electrodes and at least one counter-electrode are positioned, wherein at least one dielectric barrier is placed between the at least two electrodes and the at least one counter-electrode;
generating a high-frequency electric voltage of such a value that it causes the generation of a plasma between the at least two electrodes and the at least one counter-electrode;
feeding into the reaction chamber a mixture, the composition of which is such that on contact with the plasma, it breaks down and generates substances able to react with the surface of the substrate;
connecting an inductance (L1, L2) in series with each of said at least two electrodes, wherein the value of said inductances (L1, L2) is such that in the case where the plasma ignites under a single electrode, the current circulating in the inductance in series with this electrode causes a magnetic flux in the other inductance, and such that the resulting voltage at the terminals of this second inductance causes an increase in the voltage at the terminals of the electrode that remains unignited forcing the ignition thereof, wherein said inductances are wound on a common magnetic core so that the resulting magnetic flux of the two inductances (L1, L2) is zero when identical currents circulate in the at least two electrodes.

2. The process according to claim 1, wherein the winding of the inductances (L1, L2) in series with each of said at least two electrodes wound on a common magnetic core is reversed.

3. The process according to claim 1, wherein the mixture fed into the reaction chamber is fed via a passage opening into a space separating the at least two electrodes.

4. The process according to claim 1, wherein the plasma is generated on either side of the substrate between the at least two electrodes and the at least one counter-electrode thereby achieving a surface treatment on each side of the substrate.

5. The process according to claim 4, wherein mixtures of different compositions are fed into the reaction chamber on either side of the substrate thereby achieving a different surface treatment on each side of the substrate.

6. The process according to claim 1, wherein two counter-electrodes facing the at least two electrodes are placed side by side and the mixture is fed via a passage into the reaction chamber opening onto a space separating the two counter-electrodes.

7. The process according to claim 1, which additionally comprises the following:
putting into operation an adjustable inductance (L) arranged in parallel with the inductance of an installation itself that generates the electric voltage thereby reducing a phase shift between the voltage and the generated current;
adapting the voltage and/or the frequency supplied by a generator circuit and/or the adjustable value (L) of the inductance at the start of or during the course of the process thereby increasing an active power/reactive power ratio.

8. The process according to claim 7, which additionally comprises the following:
adapting the voltage and/or the frequency supplied by the generator circuit and/or the adjustable value (L) of the inductance thereby stimulating the production of harmonics that extend the time, during which the voltage remains higher than the value of maintaining the electric discharge.

9. The process according to claim 8, wherein harmonics in the order of 3 and 5 are essentially stimulated.

10. The process according to claim 1, which additionally comprises the following:
bringing the atmosphere prevailing in the chamber to a pressure lower than atmospheric pressure.

11. The process according to claim 1, wherein the chamber is open and comprises an inlet zone and an outlet zone for the substrate.

12. The process according to claim 1, wherein the substrate is insulating and itself forms at least one of the dielectric barriers.

13. An apparatus adapted for the surface treatment of a substrate by dielectric barrier discharge (DBD) comprising a chamber, transport means and support means for inserting a substrate into the chamber, a high-voltage and high-frequency power supply connected to at least two electrodes and at least one counter-electrode, wherein said at least two electrodes and said at least one counter-electrode are arranged on either side of the transport and support means of the substrate, at least one dielectric barrier arranged between the at least two electrodes and the at least one counter-electrode, means for adjusting and controlling the power supply, means for feeding reactive substances into the chamber, means for extracting background substances, which apparatus is adaptable for generating a plasma for the surface treatment of the substrate,
wherein inductances are switched in series with each of said electrodes, wherein the value of said inductances (L1, L2) is such that in the case where the plasma ignites under a single electrode, the current circulating in the inductance in series with this electrode causes a magnetic flux in the other inductance, and such that the resulting voltage at the terminals of this second inductance causes an increase in the voltage at the terminals of the electrode that remains unignited forcing the ignition thereof, wherein said inductances are wound on a common magnetic core so that the resulting magnetic flux of the two inductances is zero when identical currents circulate in the two electrodes.

14. The apparatus according to claim 13, wherein the plasma is generated in two separate zones arranged on either side of the substrate in such a manner that a treatment is conducted on each of the faces of this substrate simultaneously.

15. An apparatus adapted for the surface treatment of a substrate by dielectric barrier discharge (DBD) comprising two chambers, transport means and support means for inserting a substrate into the chambers, a single high-voltage and high-frequency power supply connected to at least two electrodes and at least one counter-electrode in a first chamber, and to at least two electrodes and at least one counter-electrode in the second chamber, wherein said at least two electrodes in the first chamber and said at least two electrodes in the second chamber and said at least one counter-electrode in the first chamber and said at least one counter-electrode in the second chamber are arranged on either side of the transport and support means of the substrate, at least one dielectric barrier arranged between the at least two electrodes in the first chamber and the at least two electrodes in the second chamber and the at least one counter-electrode in the first chamber and the at least one counter-electrode in the second chamber, means for adjusting and controlling the power supply, means for feeding reactive substances into the chambers, means for extracting background substances, which apparatus is adaptable for generating a plasma for the surface treatment of the substrate in each chamber,
wherein, for each chamber separately, primary inductances are switched in series with said electrodes, wherein the value of said primary inductances (L1, L2 and L3, L4) is such that in the case where the plasma ignites under a single electrode, the current circulating in the primary inductance in series with this electrode causes a magnetic flux in the other primary inductance, and such that the resulting voltage at the terminals of this other primary inductance causes an increase in the voltage at the terminals of the electrode that remains unignited forcing the ignition thereof, wherein said primary inductances are wound on a common magnetic core so that the resulting magnetic flux of the two primary inductances is zero when identical currents circulate in the two electrodes, and wherein secondary inductances are switched in series with said primary inductances, wherein the value of said additional secondary inductances (L5, L6) is such that the current circulating in the first secondary inductance in series with the first chamber causes a magnetic flux in the other secondary inductance, and such that the resulting voltage at the terminals of this other secondary inductance ensures equilibrate the voltages between the two chambers, wherein said secondary inductances are wound on a common magnetic core so that the resulting magnetic flux of the two secondary inductances is zero when identical currents circulate in the two chambers.
